(19) United States
(12) Patent Application Publication
(10) Pub. No.: US 2018/0231816 A1
(43) Pub. Date: Aug. 16, 2018

(54) THIN FILM TRANSISTOR AND MANUFACTURING METHOD THEREOF, LIQUID CRYSTAL PANEL

(71) Applicant: Shenzhen China Star Optoelectronics Technology Co., Ltd., Shenzhen, Guangdong (CN)

(72) Inventor: Guihua HUANG, Shenzhen, Guangdong (CN)

(73) Assignee: Shenzhen China Star Optoelectronics Technology Co., Ltd., Shenzhen, Guangdong (CN)

(21) Appl. No.: 15/509,506

(22) PCT Filed: Feb. 16, 2017
(86) PCT No.: PCT/CN2017/073802

§ 371 Date: Mar. 8, 2017

(30) Foreign Application Priority Data
Jan. 23, 2017 (CN) 201710058106.0

(51) Int. Cl. G02F 1/1343; H01L 27/12; G02F 1/1339

(52) U.S. Cl. CPC G02F 1/1343; H01L 27/1214; G02F 2201/123; G02F 2001/134318; G02F 2201/121; G02F 1/1339

(57) ABSTRACT

The disclosure provides a thin film transistor, including a substrate. The substrate is deposited with a patterned source electrode and a patterned common electrode. The source electrode and the common electrode are covered by a spacer layer. A side of the source electrode away from the common electrode uncovered by the spacer layer is formed to be an exposure component. A drain electrode is deposited and patterned on the spacer layer to form a pixel electrode. The pixel electrode on a side of the source electrode, the exposure component and a side of the substrate towards the source electrode are deposited with a patterned semiconductor layer, a gate insulating layer and a patterned gate electrode in sequence to form a semiconductor channel whose cross-section is a stair structure. The pixel electrode is connected with the source electrode by the semiconductor layer. The disclosure further provides a manufacturing method.

### TECHNICAL FIELD

The disclosure relates to a display technical field, and more particularly to a thin film transistor based on an IPS structure, a manufacturing method thereof and a liquid crystal panel.

### DESCRIPTION OF RELATED ART

A semiconductor channel of a thin film transistor (TFT) device in a conventional TFT array substrate generally adopts a two-dimensional planar structure. A length of the channel will be produced to be long, which restricts a switching ratio of the TFT device. A size of the TFT device in the TFT array substrate is large, which reduces an aperture ratio. Multiple masks (generally at least 5 masks) are required in a TFT manufacturing process. The process is complicated and costs are relatively high. All of above limit the development of the TFT array substrate.

### SUMMARY

In order to overcome shortcomings of the prior art, the disclosure provides a thin film transistor, a manufacturing method thereof and a liquid crystal panel to increase a switching ratio of a TFT device as well as an aperture ratio.

The disclosure provides a thin film transistor, including a substrate. The substrate is deposited with a patterned source electrode and a patterned common electrode. The source electrode and the common electrode are covered by a spacer layer. A side of the source electrode away from the common electrode uncovered by the spacer layer is formed to be an exposure component. A drain electrode is deposited and patterned on the spacer layer to form a pixel electrode. The pixel electrode on a side of the source electrode, the exposure component and a side of the substrate towards the source electrode are deposited with a patterned semiconductor layer, a gate insulating layer and a patterned gate electrode in sequence to form a semiconductor channel whose cross-section is a stair structure. The pixel electrode is connected with the source electrode by the semiconductor layer.

In an embodiment of the disclosure, a slope angle of the drain electrode and the spacer layer is 45-60 degrees.

In an embodiment of the disclosure, the spacer layer is made out of SiOx or SiNx.

In an embodiment of the disclosure, a thickness of the spacer layer is 300-1200 nm.

In an embodiment of the disclosure, material of the semiconductor layer is IGZO or a-Si.

In an embodiment of the disclosure, source electrode and the drain electrode are formed by a layer of metallic layer, or a metallically multilayer structure formed by a plurality of metallic layers.

In an embodiment of the disclosure, a thickness of the source electrode and the drain electrode is 100-400 nm.

The disclosure further provides a manufacturing method of a thin film transistor, including following steps.

Step one, depositing a source electrode and a common electrode on a substrate respectively, and patterning the source electrode and the common electrode respectively.

Step two, depositing a spacer layer and a drain electrode on the source electrode and the common electrode, etching the spacer layer and the drain electrode on a side of the source electrode away from the common electrode to form the side of the source electrode away from the common electrode to be an exposure component, patterning the drain electrode to form a pixel electrode.

Step three, a side of the substrate towards the source electrode, the exposure component of the source electrode and a side of the pixel electrode towards the source electrode deposited with a semiconductor layer, patterning the semiconductor layer and subsequently depositing a gate insulating layer on the semiconductor layer; depositing and patterning a gate electrode on the gate insulating layer to obtain a semiconductor channel whose cross-section is a stair structure, the source electrode connected with the pixel electrode by the semiconductor layer.

In an embodiment of the disclosure, a slope angle of the drain electrode and the spacer layer in the step one and the step two is 45-60 degrees.

The disclosure further provides a liquid crystal panel, including a TFT array substrate. The TFT array substrate includes the thin film transistor.

Compared with the prior art, the disclosure disposes the semiconductor channel of the thin film transistor to be the stair structure for increasing the switching ratio of the thin film transistor and the aperture ratio. The drain electrode as the pixel electrode is formed to be an IPS structure, which can be applied in a panel with high solution. The thin film transistor is produced by three procedures, which simplifies the process and reduces costs.

### BRIEF DESCRIPTION OF THE DRAWINGS

FIG. 1 is a structural schematic view of step one in a manufacturing method of a thin film transistor according to the disclosure.

FIG. 2 is a structural schematic view of step two in a manufacturing method of a thin film transistor according to the disclosure.

FIG. 3 is a structural schematic view of step three in a manufacturing method of a thin film transistor according to the disclosure.

FIG. 4 is a plane projection view of the disclosure.

### DETAILED DESCRIPTION OF PREFERRED EMBODIMENTS

The disclosure will be described in detail with reference to embodiments and the accompanying drawings as follows.

As shown in FIG. 2 and FIG. 3, a thin film transistor of the disclosure includes a substrate 1. The substrate 1 is deposited with a patterned source electrode 2 and a patterned common (COM) electrode 3. The source electrode 2 and the COM electrode 3 are disposed on a same layer. The source electrode 2 and the COM electrode 3 are covered by a spacer layer 4. A side of the source electrode 2 away from the COM electrode 3 (left side in FIG. 3) uncovered by the spacer layer 4 is formed to be an exposure component 5, depositing and patterning a drain electrode on the spacer layer 4 to form a pixel electrode 6. The pixel electrode 6 on a side of the source electrode 2 (the left side in FIG. 3), the exposure component 5 and a side of the substrate 1 towards the source electrode 2 are deposited with a patterned semiconductor layer 8, a gate insulating layer 9 and a patterned gate electrode 10 in sequence to form a semiconductor channel 7 whose cross-section is a stair structure. The pixel electrode 6 is connected with the source electrode 2 by the semiconductor layer 8. The disclosure produces the semiconductor channel 7 to be the stair structure with a vertical surface for enhancing the switching ratio and the aperture ratio of the thin film transistor. The drain electrode is additionally applied as the pixel electrode with an IPS structure, which can be equipped on a panel with high solution.

The semiconductor layer 8, the gate insulating layer 9 and the gate electrode 10 are higher than a surface of the pixel electrode 6 in the disclosure.

A slope angle of the drain electrode and the spacer layer 4 is 45-60 degrees for following deposition of membranous layers.

Specifically, the spacer layer 4 is made out of SiOx or SiNx. A thickness of the spacer layer 4 is 300-1200 nm. Material of the semiconductor layer 8 is IGZO or a-Si. The source electrode 2 and the drain electrode are formed by a layer of metallic layer, or a metallically multilayer structure formed by a plurality of metallic layers, such as metallic multilayers formed by Mo, Mo/Al/Mo, Mo/Ti, etc., the thickness is 100-400 nm.

A manufacturing method of a thin film transistor of the disclosure includes following steps.

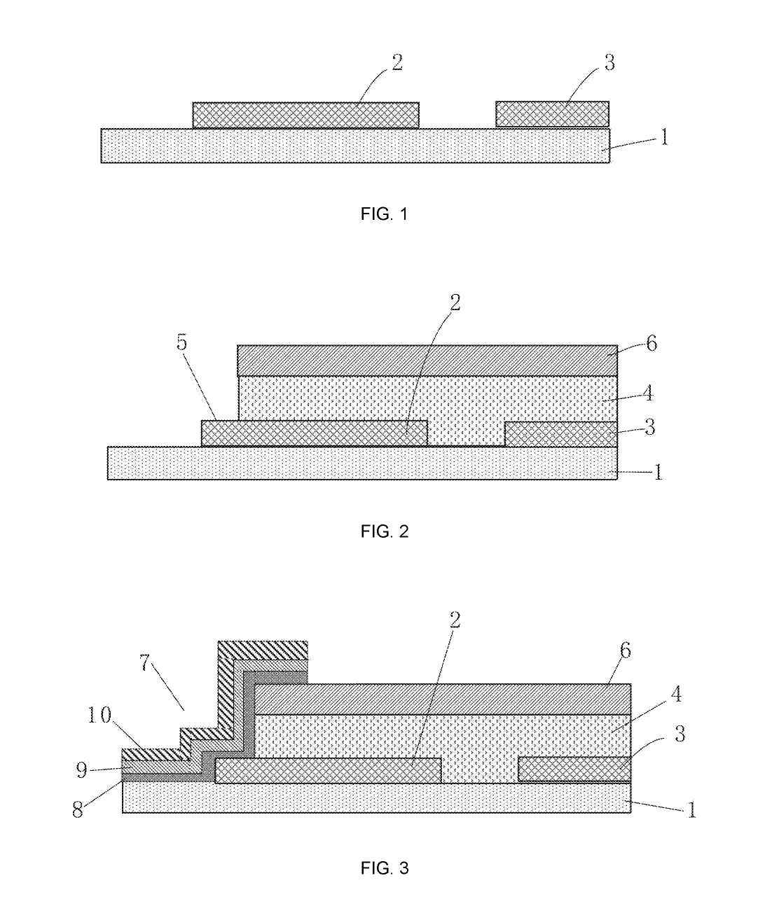

Step one, as shown in FIG. 1, depositing the source electrode 2 and the COM electrode 3 on the substrate 1 respectively by the prior art, and patterning the source electrode 2 and the COM electrode 3 respectively.

Step two, as shown in FIG. 2, depositing the spacer layer 4 and the drain electrode on the source electrode 2 and the COM electrode 3 by the prior art, etching the spacer layer 4 and the drain electrode on a side of the source electrode 2 away from the COM electrode 3 (left side in FIG. 2) to form the side of the source electrode 2 away from the COM electrode 3 to be an exposure component 5, patterning the drain electrode to form the pixel electrode 6.

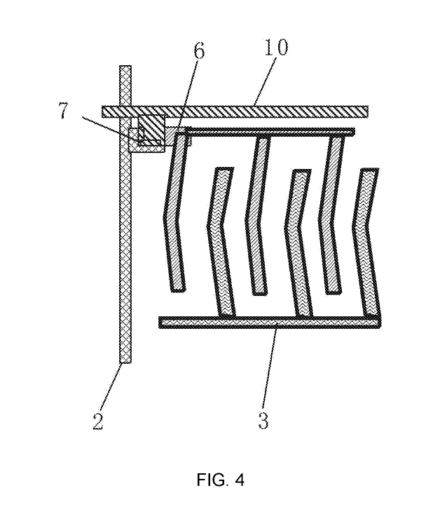

Step three, as shown in FIGS. 2-4, a side of the substrate 1 towards the source electrode 2, the exposure component 5 of the source electrode 2 and a side of the pixel electrode 6 towards the source electrode 2 are deposited with the semiconductor layer 8, patterning the semiconductor layer 8 and subsequently depositing the gate insulating layer 9 on the semiconductor layer 8; depositing and patterning the gate electrode 10 on the gate insulating layer 9 to obtain the semiconductor channel 7 whose cross-section is a stair structure; the source electrode 2 is connected with the pixel electrode 6 by the semiconductor layer 8.

A slope angle of the drain electrode and the spacer layer 4 in the step one and the step two is 45-60 degrees.

Specifically, the spacer layer 4 is made out of SiOx or SiNx. A thickness of the spacer layer 4 is 300-1200 nm. Material of the semiconductor layer 8 is IGZO or a-Si. The source electrode 2 and the drain electrode are formed by a layer of metallic layer, or a metallically multilayer structure formed by a plurality of metallic layers, such as metallic multilayers formed by Mo, Mo/Al/Mo, Mo/Ti, etc., the thickness is 100-400 nm.

The drain electrode and the spacer layer 4 are processed by dry etching and wet etching.

The manufacturing method of a thin film transistor of the disclosure merely requires three procedures to prepare the thin film transistor, which simplifies the process and reduces costs.

The disclosure further discloses a liquid crystal panel. The TFT array substrate includes the thin film transistor described above, which will not be repeated.

Although the disclosure is illustrated with reference to specific embodiments, a person skilled in the art should understand that various modifications on forms and details can be achieved within the spirit and scope of the disclosure limited by the claims and the counterpart.

What is claimed is:

1. A thin film transistor, comprising a substrate, the substrate deposited with a patterned source electrode and a patterned common electrode, the source electrode and the common electrode covered by a spacer layer, a side of the source electrode away from the common electrode uncovered by the spacer layer formed to be an exposure component, depositing and patterning a drain electrode on the spacer layer to form a pixel electrode, the pixel electrode on a side of the source electrode, the exposure component and a side of the substrate towards the source electrode deposited with a patterned semiconductor layer, a gate insulating layer and a patterned gate electrode in sequence to form a semiconductor channel whose cross-section is a stair structure, the pixel electrode connected with the source electrode by the semiconductor layer.

2. The thin film transistor according to claim 1, wherein a slope angle of the drain electrode and the spacer layer is 45-60 degrees.

3. The thin film transistor according to claim 1, wherein the spacer layer is made out of SiOx or SiNx.

4. The thin film transistor according to claim 1, wherein a thickness of the spacer layer is 300-1200 nm.

5. The thin film transistor according to claim 2, wherein a thickness of the spacer layer is 300-1200 nm.

6. The thin film transistor according to claim 1, wherein material of the semiconductor layer is IGZO or a-Si.

7. The thin film transistor according to claim 1, wherein the source electrode and the drain electrode are formed by a layer of metallic layer, or a metallically multilayer structure formed by a plurality of metallic layers.

8. The thin film transistor according to claim 1, wherein a thickness of the source electrode and the drain electrode is 100-400 nm.

9. The thin film transistor according to claim 6, wherein a thickness of the source electrode and the drain electrode is 100-400 nm.

10. A manufacturing method of a thin film transistor, comprising following steps:
step one, depositing a source electrode and a common electrode on a substrate respectively, and patterning the source electrode and the common electrode respectively;
step two, depositing a spacer layer and a drain electrode on the source electrode and the common electrode, etching the spacer layer and the drain electrode on a side of the source electrode away from the common electrode to form the side of the source electrode away from the common electrode to be an exposure component, patterning the drain electrode to form a pixel electrode;
step three, a side of the substrate towards the source electrode, the exposure component of the source electrode and a side of the pixel electrode towards the source electrode deposited with a semiconductor layer, patterning the semiconductor layer and subsequently depositing a gate insulating layer on the semiconductor layer; depositing and patterning a gate electrode on the gate insulating layer to obtain a semiconductor channel whose cross-section is a stair structure, the source electrode connected with the pixel electrode by the semiconductor layer.

11. The manufacturing method of a thin film transistor according to claim 10, wherein a slope angle of the drain electrode and the spacer layer in the step one and the step two is 45-60 degrees.

12. A liquid crystal panel, comprising a TFT array substrate, the TFT array substrate comprising a thin film transistor, the thin film transistor comprising a substrate, the substrate deposited with a patterned source electrode and a patterned common electrode, the source electrode and the common electrode covered by a spacer layer, a side of the source electrode away from the common electrode uncovered by the spacer layer to form an exposure component, the spacer layer deposited with a drain electrode, patterning the drain electrode to form a pixel electrode, a side of the pixel electrode towards source electrode, the exposure component and a side of the substrate towards the source electrode deposited with a patterned semiconductor layer, a gate insulating layer and a patterned gate electrode in sequence to form a semiconductor channel whose cross-section is a stair structure, the pixel electrode connected with the source electrode by the semiconductor layer.

13. The liquid crystal panel according to claim 12, wherein a slope angle of the drain electrode and the spacer layer is 45-60 degrees.

14. The liquid crystal panel according to claim 12, wherein the spacer layer is made out of SiOx or SiNx.

15. The liquid crystal panel according to claim 12, wherein a thickness of the spacer layer is 300-1200 nm.

16. The liquid crystal panel according to claim 13, wherein a thickness of the spacer layer is 300-1200 nm.

17. The liquid crystal panel according to claim 12, wherein material of the semiconductor layer is IGZO or a-Si.

18. The liquid crystal panel according to claim 12, wherein the source electrode and the drain electrode are formed by a layer of metallic layer, or a metallically multilayer structure formed by a plurality of metallic layers.

19. The liquid crystal panel according to claim 12, wherein a thickness of the source electrode and the drain electrode is 100-400 nm.

20. The liquid crystal panel according to claim 14, wherein a thickness of the source electrode and the drain electrode is 100-400 nm.
